(19) United States
(12) Patent Application Publication
(10) Pub. No.: US 2007/0222469 A1
(43) Pub. Date: Sep. 27, 2007

(54) CIRCUIT BOARD ASSEMBLY AND INVERTER UTILIZING THE SAME

(75) Inventors: CHIH-CHAN GER, Shenzhen (CN); YU-HSIANG LIAO, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,584

(22) Filed: Aug. 25, 2006

(30) Foreign Application Priority Data
Mar. 23, 2006 (CN) 200620056985.0

(51) Int. Cl. G01R 31/02

(52) U.S. Cl. 324/763

(57) ABSTRACT

An inverter includes a first circuit board (100) including a plurality of first conductor trace lines (102) for providing electronic connections among a plurality of electronic components disposed thereon, and a second circuit board (200) including a plurality of second conductor trace lines (202) for providing electronic connections among a plurality of electronic components disposed thereon. The second circuit board is disposed above the first circuit board, and is substantially perpendicular with and electrically connected to the first circuit board via at least one of the second conductor trace lines and at least one of the first conductor trace lines.

### FIELD OF THE INVENTION

The invention relates to circuit board assemblies, and particularly to a circuit board assembly and an inverter utilizing the same.

### DESCRIPTION OF RELATED ART

Inverters are commonly used for converting low voltage direct current (DC) to high voltage alternating current (AC) in liquid crystal display (LCD) monitors. Therefore, each inverter includes low voltage DC circuits and high voltage AC circuits disposed on a printed circuit board (PCB) thereof. The high voltage AC circuits often produce electromagnetic interference (EMI) signals interfering with the low voltage DC circuits and electronic components disposed on the PCB of the inverter, thus, reducing the performance of the inverters. Furthermore, the high voltage AC circuits may suffer sudden high level electric current discharges and damage the electronic components disposed on the PCB of the inverter.

A conventional approach for solving this problem is to increase the number of layers of a PCB. As is generally known, PCBs are mainly categorized as single-sided boards, double-sided boards, or multi-layer boards. A single-sided board has conductors (copper traces) on only one side of the board. A double-sided board has conductors on two opposite sides of the board. A multi-layer circuit board is equivalent to an integrated combination of a plurality of single-sided boards and/or double-sided boards. A conventional approach in designing an inverter circuit utilizes a double-sided board or a multi-layer board to separate the high voltage AC circuits from the low voltage DC circuits. This approach, however, increases the cost of the PCBs since the costs of the double-sided boards and the multi-layer boards are higher than that of a single-sided board.

Another conventional approach for solving this problem is to increase the area of the PCB and re-arrange and separate the high voltage AC circuits and the low voltage DC circuits on the PCB so as to prevent interference between the high voltage AC circuits and the low voltage DC circuits. However, since the area of the PCB of the inverter is increased, the size of electronic devices utilizing the inverter cannot be reduced.

Therefore, a heretofore unaddressed need exists in the industry to overcome the aforementioned deficiencies and inadequacies.

### SUMMARY OF THE INVENTION

An aspect of the invention provides a circuit board assembly. The circuit board assembly includes a first circuit board and a second circuit board. The first circuit board includes a plurality of first conductor trace lines for providing electronic connections among a plurality of electronic components disposed thereon. The second circuit board includes a plurality of second conductor trace lines for providing electronic connections among a plurality of electronic components disposed thereon. The second circuit board is disposed above the first circuit board, and is substantially perpendicular with and electrically connected to the first circuit board via at least one of the second conductor trace lines and at least one of the first conductor trace lines.

Another aspect of the invention provides an inverter. The inverter includes a first circuit board and a second circuit board. The first circuit board includes a plurality of first conductor trace lines for providing electronic connections among a plurality of electronic components disposed thereon. The second circuit board includes a plurality of second conductor trace lines for providing electronic connections among a plurality of electronic components disposed thereon. The second circuit board is disposed above the first circuit board, and is substantially perpendicular with and electrically connected to the first circuit board via at least one of the second conductor trace lines and at least one of the first conductor trace lines.

Other advantages and novel features will become more apparent from the following detailed description of preferred embodiments when taken in conjunction with the accompanying drawings, in which:

### BRIEF DESCRIPTION OF THE DRAWINGS

FIG. 1 is a schematic, cross-sectional side view of a circuit board assembly of an exemplary embodiment of the present invention;

FIG. 2 is a schematic, cross-sectional side view of a circuit board assembly of another exemplary embodiment of the present invention;

FIG. 3 is a schematic, cross-sectional side view of a circuit board assembly of still another exemplary embodiment of the present invention;

FIG. 4 is a schematic, cross-sectional side view of a circuit board assembly of yet still another exemplary embodiment of the present invention;

### DETAILED DESCRIPTION OF THE INVENTION

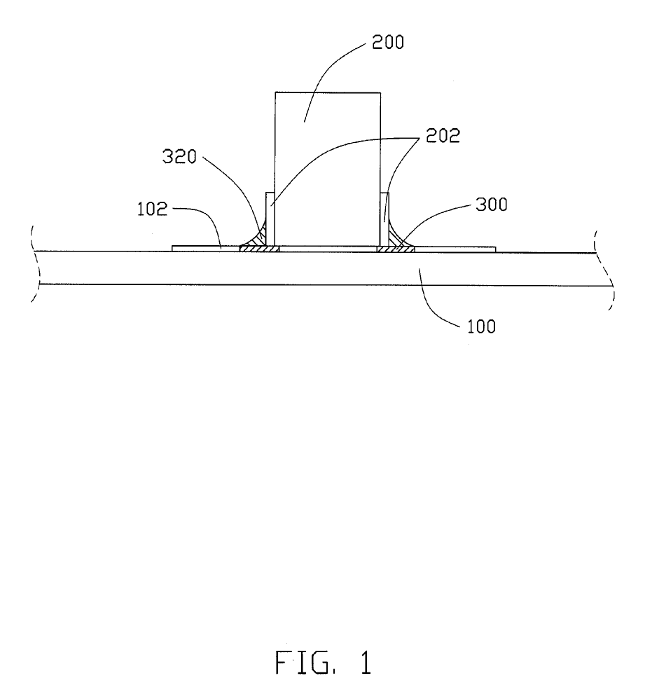

FIG. 1 is a schematic, cross-sectional side view of a circuit board assembly of an exemplary embodiment of the present invention. The circuit board assembly comprises a first circuit board 100 and a second circuit board 200. The second circuit board 200 is disposed above and perpendicular to the first circuit board 100. Note that the circuit board assembly of the invention can be a stand-alone product, a part of an inverter, or a part of another electronic device.

In the exemplary embodiment, the first circuit board 100 is a single-sided board, and the second circuit board 200 is a double-sided board. The first circuit board 100 is typically used as a primary circuit board for a layout of a plurality of electronic components disposed thereon, and the second circuit board 200 also has a plurality of electronic components disposed thereon. Preferably, the second circuit board 200 has a smaller surface area than the first circuit board 100, and the width of the second circuit board 200 is less than the height of the highest electronic component disposed on the first circuit board 100 thus reducing the thickness of the circuit board assembly. In an alternative embodiment, in particular, the width of the second circuit board 200 is equal to, or greater than the height of the highest electronic component disposed on the first circuit board 100.

The first circuit board 100 comprises a plurality of first conductor trace lines 102 disposed on a top surface thereof, for providing electrical connections among the electronic components disposed thereon. The first conductor trace lines 102 are typically etched copper foils.

The second circuit board 200 comprises a plurality of second conductor trace lines 202 disposed on opposite surfaces thereof, for providing electrical connections among the electronic components disposed thereon. The second conductor trace lines 202 are typically etched copper foils. In the exemplary embodiment, a plurality of vias (not shown) are embedded in the second circuit board 200. A metal layer (not shown) is formed on an inner wall of each via, for electrically connecting the second conductor trace lines 202 disposed on the opposite surfaces of the second circuit board 200.

The circuit board assembly further comprises a plurality of solder pads 300 disposed on the top surface of the first circuit board 100 and electrically connected to the first conductor trace lines 102, and a plurality of solder portions 320 disposed between the solder pads 300 and the second conductor trace lines 202 for electrically connecting the first conductor trace lines 102 to the respective second conductor trace lines 202.

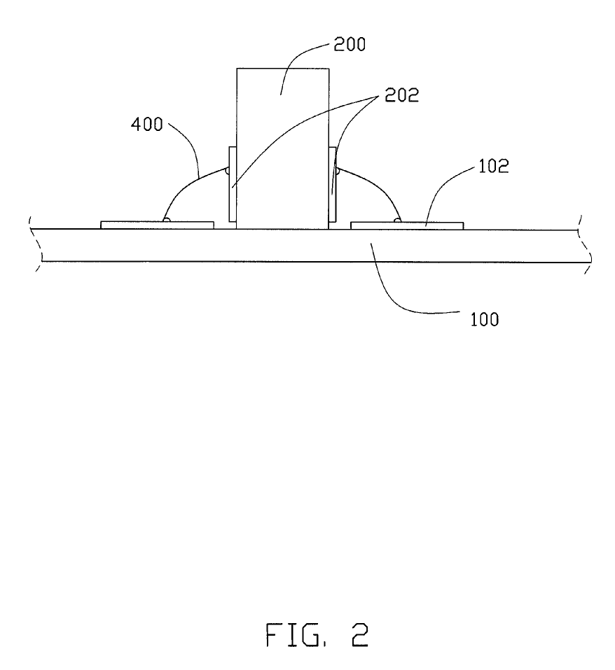

FIG. 2 is a schematic, cross-sectional side view of a circuit board assembly of another exemplary embodiment of the present invention. The first conductor trace lines 102 of the first circuit board 100 and the second conductor trace lines 202 of the second circuit board 200 shown in FIG. 2 have similar connections to those connections shown in FIG. 1. However, in the exemplary embodiment, the circuit board assembly further comprises at least one solder wire 400, for electrically connecting at least one of the first conductor lines 102 of the first circuit board 100 to at least one respective second conductor line 202 of the second circuit board 200. In particular, the at least one solder wire 400 is connected to at least one of the respective first conductor lines 102 and at least one of the respective second conductor lines 202 by a wire soldering process.

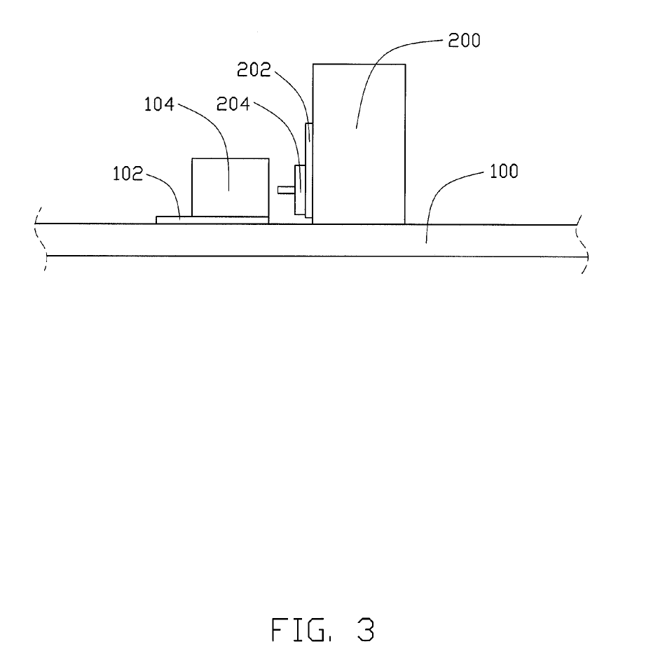

FIG. 3 is a schematic, cross-sectional side view of a circuit board assembly of still another exemplary embodiment of the present invention. The first conductor trace lines 102 of the first circuit board 100 and the second conductor trace lines 202 of the second circuit board 200 shown in FIG. 3 have similar connections to those connections shown in FIG. 1. However, in the exemplary embodiment, the first circuit board 100 further comprises a first connector 104 electrically connected to the first conductor trace lines 102, while the second circuit board 200 further comprises a second connector 204 electrically connected to the second conductor trace lines 202. In the exemplary embodiment, the first connector 104 is a female connector, while the second connector 204 is a male connector. The second connector 204 is inserted into the first connector 104 along a direction parallel with the top surface of the first circuit board 100, and is thus engaged with and electrically connected to the first connector 104. Alternatively, the first connector 104 is a male connector, while the second connector 204 is a female connector.

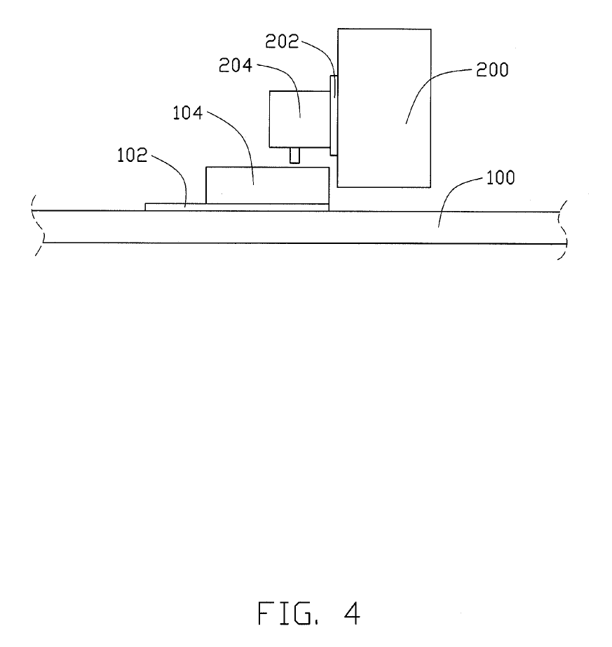

FIG. 4 is a schematic, cross-sectional side view of a circuit board assembly of yet still another exemplary embodiment of the present invention. The first conductor trace lines 102 of the first circuit board 100 and the second conductor trace lines 202 of the second circuit board 200 shown in FIG. 4 have similar connections to those connections shown in FIG. 3. However, in the exemplary embodiment, the difference is that the second connector 204 is inserted into the first connector 104 along a direction parallel with the opposite surfaces of the second circuit board 200, and is thus engaged with and electrically connected to the first connector 104.

In any of the above-described embodiments shown in FIG. 1 to FIG. 4, preferably, complex or high voltage circuits are disposed on the second circuit board 200, and other simple circuits are disposed on the first circuit board 200. The second circuit board 200 is typically a more expensive double-sided board with a smaller surface area. The first circuit board 100 is typically a less expensive single-sided board that serves as the primary circuit board with a larger surface area. Thus, the circuit board assembly can provide circuits with great complexity and high reliability at a relatively low cost.

In addition, in alternative embodiments of any of the above-described embodiments shown in FIG. 1 to FIG. 4, the second circuit board 200 is a multi-layer board and is relatively thin. Hence, capacitors with either high capacitance or low capacitance can be formed and embedded in the PCB assembly.

In alternative embodiments of any of the above-described embodiments shown in FIG. 1 to FIG. 4 and alternatives thereof, the first circuit board 100 can be a double-sided board. Furthermore, means of connecting the first conductor trace lines 102 of the first circuit board 100 to the respective second conductor trace lines 202 of the second circuit board 200 can be any suitable one or combination of the means described above in relation to the embodiments shown in FIG. 1 to FIG. 4 and alternatives thereof.

While exemplary embodiments of the present invention have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A circuit board assembly, comprising:
a first circuit board comprising a plurality of first conductor trace lines for providing electronic connections among a plurality of electronic components disposed thereon; and
a second circuit board comprising a plurality of second conductor trace lines for providing electronic connections among a plurality of electronic components disposed thereon;
wherein the second circuit board is disposed above the first circuit board, and is substantially perpendicular with and electrically connected to the first circuit board via at least one of the second conductor trace lines and at least one of the first conductor trace lines.

2. The circuit board assembly as claimed in claim 1, wherein the first circuit board is a single-sided board.

3. The circuit board assembly as claimed in claim 2, wherein the first conductor trace lines are disposed on a top surface of the first circuit board.

4. The circuit board assembly as claimed in claim 2, wherein the second circuit board is a double-sided board having two opposite surfaces, and the second conductor trace lines are disposed on the opposite surfaces of the second circuit board.

5. The circuit board assembly as claimed in claim 2, wherein the second circuit board is a multi-layer board having two opposite surfaces and a plurality of inner faces, and the second conductor trace lines are disposed on the opposite surfaces and the inner faces of the second circuit board.

6. The circuit board assembly as claimed in claim 1, further comprising at least one solder pad disposed on a top surface of the first circuit board and electrically connected to the first conductor trace lines of the first circuit board.

7. The circuit board assembly as claimed in claim 6, further comprising at least one solder portion disposed between one of the at least one solder pad and the corresponding second conductor trace line, wherein the at least one solder portion electrically connects at least one of the first conductor trace lines to at least one respective second conductor trace line.

8. The circuit board assembly as claimed in claim 1, further comprising at least one solder wire connecting at least one of the first conductor trace lines to at least one respective second conductor trace line.

9. The circuit board assembly as claimed in claim 1, wherein the first circuit board and the second circuit board each further comprises a connector, and the connector of the first circuit board is engaged with and electrically connected to the connector of the second circuit board.

10. An inverter, comprising:
a first circuit board comprising a plurality of first conductor trace lines for providing electronic connections among a plurality of electronic components disposed thereon; and
a second circuit board comprising a plurality of second conductor trace lines for providing electronic connections among a plurality of electronic components disposed thereon;
wherein the second circuit board is disposed above the first circuit board, and is substantially perpendicular with and electrically connected to the first circuit board via at least one of the second conductor trace lines and at least one of the first conductor trace lines.

11. The inverter as claimed in claim 10, wherein the first circuit board is a single-sided board.

12. The inverter as claimed in claim 11, wherein the first conductor trace lines are disposed on a top surface of the first circuit board.

13. The inverter as claimed in claim 11, wherein the second circuit board is a double-sided board having two opposite surfaces, and the second conductor trace lines are disposed on the opposite surfaces of the second circuit board.

14. The inverter as claimed in claim 11, wherein the second circuit board is a multi-layer board having two opposite surfaces and a plurality of inner faces, and the second conductor trace lines are disposed on the opposite surfaces and the inner faces of the second circuit board.

15. The inverter as claimed in claim 10, further comprising at least one solder pad disposed on a top surface of the first circuit board and electrically connected to the first conductor trace lines of the first circuit board.

16. The inverter as claimed in claim 15, further comprising at least one solder portion disposed between one of the at least one solder pad and the corresponding second conductor trace line, wherein the at least one solder portion electrically connects at least one of the first conductor trace lines to at least one respective second conductor trace line.

17. The inverter as claimed in claim 10, further comprising at least one solder wire connecting at least one of the first conductor trace lines to at least one respective second conductor trace line.

18. The inverter as claimed in claim 10, wherein the first circuit board and the second circuit board each further comprises a connector, and the connector of the first circuit board is engaged with and electrically connected to the connector of the second circuit board.
